(19) United States
(12) Patent Application Publication
(10) Pub. No.: US 2026/0290476 A1
(43) Pub. Date: Sep. 24, 2026

(54) Data Storage Device and Method for Request Clustering for Improved Read Threshold Calibration

(71) Applicant: Sandisk Technologies, Inc., Milpitas, CA (US)

(72) Inventors: David Avraham, San Jose, CA (US); Ariel Navon, Revava (IL); Alexander Bazarsky, Holon (IL); Eran Sharon, Rishon Lezion (IL)

(73) Assignee: Sandisk Technologies, Inc., Milpitas, CA (US)

(21) Appl. No.: 19/087,919

(22) Filed: Mar. 24, 2025

(51) Int. Cl. G11C 16/34; G11C 16/26

(52) U.S. Cl. CPC G11C 16/3418; G11C 16/26; G11C 2207/2254

(57) ABSTRACT

In some data storage devices, read thresholds used for reading a memory page are not fixed and can change significantly as a function of various conditions. The data storage device can perform a read threshold calibration operation for every read request to ensure that the data storage device is reading the memory with an accurate read threshold. However, performing the operation for every read request can reduce power consumption and require costly hardware. To overcome this issue, one example data storage device described herein applies a clustering method to reduce the read threshold calibration operations that are performed. In another example, recently-calculated read thresholds are cached, so they can be provided without recalculation if conditions are similar.

### BACKGROUND

Data storage devices often need to support a wide range of operational conditions, such as different program/erase cycles, retention times, and temperatures, which can lead to increased variability between memory dies, blocks, and pages across the different operational conditions. Due to these variations, the read thresholds used for reading a memory page are not fixed and can change significantly as a function of the physical location and the operational conditions, especially for less-mature, new memory nodes. Reading with inaccurate read thresholds can lead to higher bit error rates, which can degrade performance and quality of service due to decoding failures.

### BRIEF DESCRIPTION OF THE DRAWINGS

FIG. 1A is a block diagram of a data storage device of an embodiment.

FIG. 1B is a block diagram illustrating a storage module of an embodiment.

FIG. 1C is a block diagram illustrating a hierarchical storage system of an embodiment.

FIG. 2A is a block diagram illustrating components of the controller of the data storage device illustrated in FIG. 1A according to an embodiment.

FIG. 2B is a block diagram illustrating components of the data storage device illustrated in FIG. 1A according to an embodiment.

FIG. 3 is a block diagram of a host and a data storage device of an embodiment.

FIG. 4 is an illustration of an example architecture of an embodiment.

FIG. 5 is an illustration of an example architecture of an embodiment.

FIG. 6 is a flow chart of a method of an embodiment for request clustering for improved read threshold calibration.

FIG. 7 is a flow chart of a method of an embodiment for request clustering for improved read threshold calibration.

### DETAILED DESCRIPTION

The following embodiments generally relate to a data storage device and method for request clustering for improved read threshold calibration. In one embodiment, a data storage device is provided comprising a memory and one or more processors. The one or more processors, individually or in combination, are configured to: receive a plurality of read requests from a host; determine a cluster of read requests in the plurality of read requests that are directed to locations in the memory that have similar memory conditions; and instead of performing a read threshold calibration operation on each read request in the cluster, perform a read threshold calibration operation only on a subset of read requests in the cluster and use a result of the read threshold calibration operation for all read requests in the cluster.

In another embodiment, a method is provided that is performed in a data storage device comprising a memory. The method comprises: caching a plurality of calculated read thresholds; receiving a read request from a host, wherein the read request is directed to a location in the memory; determining whether a condition of the location in the memory is similar to a condition associated with one of the cached plurality of calculated read thresholds; and in response to determining that the condition of the location in the memory is similar to the condition associated with the one of the cached plurality of calculated read thresholds, using the one of the cached plurality of calculated read thresholds for the read request instead of calculating a new read threshold for the read request.

In yet another embodiment, a data storage device is provided comprising: a memory; and means for: receiving a plurality of read requests from a host; identifying a cluster of read requests in the plurality of read requests that are directed to locations in the memory that have similar conditions; and instead of performing a read threshold calibration operation on each read request in the cluster, performing a read threshold calibration operation only on a subset of read requests in the cluster and use a result of the read threshold calibration operation for all read requests in the cluster.

Other embodiments are possible, and each of the embodiments can be used alone or together in combination. Accordingly, various embodiments will now be described with reference to the attached drawings.

### EMBODIMENTS

The following embodiments relate to a data storage device (DSD). As used herein, a “data storage device” refers to a non-volatile device that stores data. Examples of DSDs include, but are not limited to, hard disk drives (HDDs), solid state drives (SSDs), tape drives, hybrid drives, etc. Details of example DSDs are provided below.

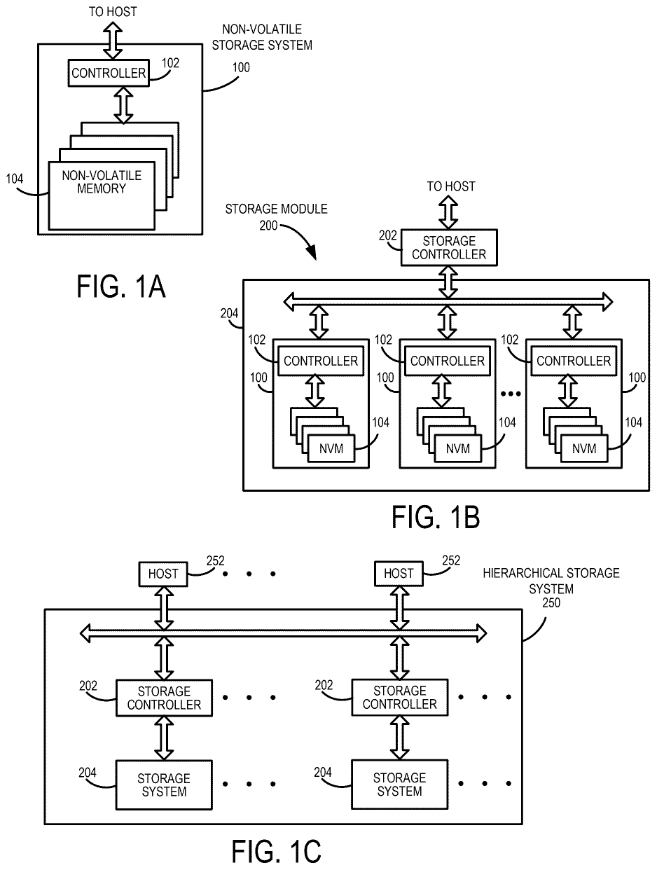

Examples of data storage devices suitable for use in implementing aspects of these embodiments are shown in FIGS. 1A-1C. It should be noted that these are merely examples and that other implementations can be used. FIG. 1A is a block diagram illustrating the data storage device 100 according to an embodiment. Referring to FIG. 1A, the data storage device 100 in this example includes a controller 102 coupled with a non-volatile memory that may be made up of one or more non-volatile memory die 104. As used herein, the term die refers to the collection of non-volatile memory cells, and associated circuitry for managing the physical operation of those non-volatile memory cells, that are formed on a single semiconductor substrate. The controller 102 interfaces with a host system and transmits command sequences for read, program, and erase operations to non-volatile memory die 104. Also, as used herein, the phrase “in communication with” or “coupled with” could mean directly in communication/coupled with or indirectly in communication/coupled with through one or more components, which may or may not be shown or described herein. The communication/coupling can be wired or wireless.

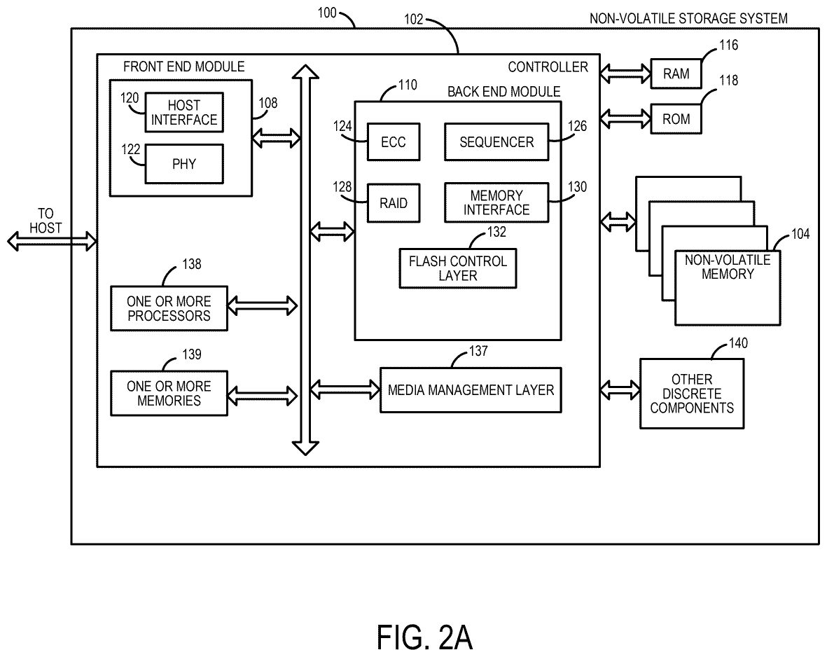

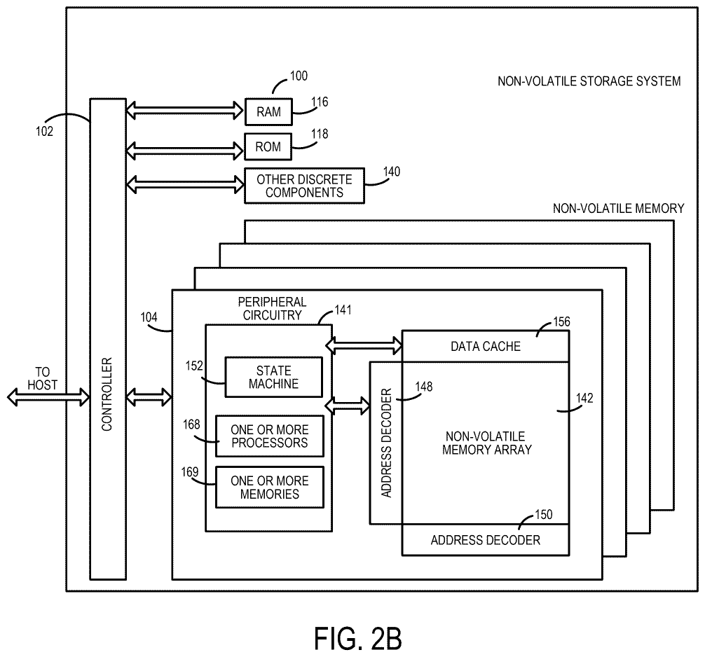

The controller 102 (which may be a non-volatile memory controller (e.g., a flash, resistive random-access memory (ReRAM), phase-change memory (PCM), or magnetoresistive random-access memory (MRAM) controller)) can include one or more components, individually or in combination, configured to perform certain functions, including, but not limited to, the functions described herein and illustrated in the flow charts. For example, as shown in FIG. 2A, the controller 102 can comprise one or more processors 138 that are, individually or in combination, configured to perform functions, such as, but not limited to the functions described herein and illustrated in the flow charts, by executing computer-readable program code stored in one or more non-transitory memories 139 inside the controller 102 and/or outside the controller 102 (e.g., in random access memory (RAM) 116 or read-only memory (ROM) 118). As another example, the one or more components can include circuitry, such as, but not limited to, logic gates, switches, an application specific integrated circuit (ASIC), a programmable logic controller, and an embedded microcontroller.

In one example embodiment, the non-volatile memory controller 102 is a device that manages data stored on non-volatile memory and communicates with a host, such as a computer or electronic device, with any suitable operating system. The non-volatile memory controller 102 can have various functionality in addition to the specific functionality described herein. For example, the non-volatile memory controller can format the non-volatile memory to ensure the memory is operating properly, map out bad non-volatile memory cells, and allocate spare cells to be substituted for future failed cells. Some part of the spare cells can be used to hold firmware (and/or other metadata used for housekeeping and tracking) to operate the non-volatile memory controller and implement other features. In operation, when a host needs to read data from or write data to the non-volatile memory, it can communicate with the non-volatile memory controller. If the host provides a logical address to which data is to be read/written, the non-volatile memory controller can convert the logical address received from the host to a physical address in the non-volatile memory. The non-volatile memory controller can also perform various memory management functions, such as, but not limited to, wear leveling (distributing writes to avoid wearing out specific blocks of memory that would otherwise be repeatedly written to) and garbage collection (after a block is full, moving only the valid pages of data to a new block, so the full block can be erased and reused).

Non-volatile memory die 104 may include any suitable non-volatile storage medium, including resistive random-access memory (ReRAM), magnetoresistive random-access memory (MRAM), phase-change memory (PCM), NAND flash memory cells and/or NOR flash memory cells. The memory cells can take the form of solid-state (e.g., flash) memory cells and can be one-time programmable, few-time programmable, or many-time programmable. The memory cells can also be single-level cells (SLC), multiple-level cells (MLC) (e.g., dual-level cells, triple-level cells (TLC), quad-level cells (QLC), etc.) or use other memory cell level technologies, now known or later developed. Also, the memory cells can be fabricated in a two-dimensional or three-dimensional fashion.

The interface between controller 102 and non-volatile memory die 104 may be any suitable flash interface, such as Toggle Mode 200, 400, or 800. In one embodiment, the data storage device 100 may be a card-based system, such as a secure digital (SD) or a micro secure digital (micro-SD) card. In an alternate embodiment, the data storage device 100 may be part of an embedded data storage device.

Although, in the example illustrated in FIG. 1A, the data storage device 100 (sometimes referred to herein as a storage module) includes a single channel between controller 102 and non-volatile memory die 104, the subject matter described herein is not limited to having a single memory channel. For example, in some architectures (such as the ones shown in FIGS. 1B and 1C), two, four, eight or more memory channels may exist between the controller and the memory device, depending on controller capabilities. In any of the embodiments described herein, more than a single channel may exist between the controller and the memory die, even if a single channel is shown in the drawings.

FIG. 1B illustrates a storage module 200 that includes plural non-volatile data storage devices 100. As such, storage module 200 may include a storage controller 202 that interfaces with a host and with data storage device 204, which includes a plurality of data storage devices 100. The interface between storage controller 202 and data storage devices 100 may be a bus interface, such as a serial advanced technology attachment (SATA), peripheral component interconnect express (PCIe) interface, double-data-rate (DDR) interface, or serial attached small scale compute interface (SAS/SCSI). Storage module 200, in one embodiment, may be a solid-state drive (SSD), or non-volatile dual in-line memory module (NVDIMM), such as found in server PC or portable computing devices, such as laptop computers, and tablet computers.

FIG. 1C is a block diagram illustrating a hierarchical storage system. A hierarchical storage system 250 includes a plurality of storage controllers 202, each of which controls a respective data storage device 204. Host systems 252 may access memories within the storage system 250 via a bus interface. In one embodiment, the bus interface may be a Non-Volatile Memory Express (NVMe) or Fibre Channel over Ethernet (FCoE) interface. In one embodiment, the system illustrated in FIG. 1C may be a rack mountable mass storage system that is accessible by multiple host computers, such as would be found in a data center or other location where mass storage is needed.

Referring again to FIG. 2A, the controller 102 in this example also includes a front-end module 108 that interfaces with a host, a back-end module 110 that interfaces with the one or more non-volatile memory die 104, and various other components or modules, such as, but not limited to, a buffer manager/bus controller module that manage buffers in RAM 116 and controls the internal bus arbitration of controller 102. A module can include one or more processors or components, as discussed above. The ROM 118 can store system boot code. Although illustrated in FIG. 2A as located separately from the controller 102, in other embodiments one or both of the RAM 116 and ROM 118 may be located within the controller 102. In yet other embodiments, portions of RAM 116 and ROM 118 may be located both within the controller 102 and outside the controller 102.

Front-end module 108 includes a host interface 120 and a physical layer interface (PHY) 122 that provide the electrical interface with the host or next level storage controller. The choice of the type of host interface 120 can depend on the type of memory being used. Examples of host interfaces 120 include, but are not limited to, SATA, SATA Express, serially attached small computer system interface (SAS), Fibre Channel, universal serial bus (USB), PCIe, and NVMe. The host interface 120 typically facilitates transfer for data, control signals, and timing signals.

Back-end module 110 includes an error correction code (ECC) engine 124 that encodes the data bytes received from the host, and decodes and error corrects the data bytes read from the non-volatile memory. A command sequencer 126 generates command sequences, such as program and erase command sequences, to be transmitted to non-volatile memory die 104. A RAID (Redundant Array of Independent Drives) module 128 manages generation of RAID parity and recovery of failed data. The RAID parity may be used as an additional level of integrity protection for the data being written into the memory device 104. In some cases, the RAID module 128 may be a part of the ECC engine 124. A memory interface 130 provides the command sequences to non-volatile memory die 104 and receives status information from non-volatile memory die 104. In one embodiment, memory interface 130 may be a double data rate (DDR) interface, such as a Toggle Mode 200, 400, or 800 interface. The controller 102 in this example also comprises a media management layer 137 and a flash control layer 132, which controls the overall operation of back-end module 110.

The data storage device 100 also includes other discrete components 140, such as external electrical interfaces, external RAM, resistors, capacitors, or other components that may interface with controller 102. In alternative embodiments, one or more of the physical layer interface 122, RAID module 128, media management layer 138 and buffer management/bus controller are optional components that are not necessary in the controller 102.

FIG. 2B is a block diagram illustrating components of non-volatile memory die 104 in more detail. Non-volatile memory die 104 includes peripheral circuitry 141 and non-volatile memory array 142. Non-volatile memory array 142 includes the non-volatile memory cells used to store data. The non-volatile memory cells may be any suitable non-volatile memory cells, including ReRAM, MRAM, PCM, NAND flash memory cells and/or NOR flash memory cells in a two-dimensional and/or three-dimensional configuration. Non-volatile memory die 104 further includes a data cache 156 that caches data and address decoders 148, 150. The peripheral circuitry 141 in this example includes a state machine 152 that provides status information to the controller 102. The peripheral circuitry 141 can also comprise one or more components that are, individually or in combination, configured to perform certain functions, including, but not limited to, the functions described herein and illustrated in the flow charts. For example, as shown in FIG. 2B, the memory die 104 can comprise one or more processors 168 that are, individually or in combination, configured to execute computer-readable program code stored in one or more non-transitory memories 169, stored in the memory array 142, or stored outside the memory die 104. As another example, the one or more components can include circuitry, such as, but not limited to, logic gates, switches, an application specific integrated circuit (ASIC), a programmable logic controller, and an embedded microcontroller.

In addition to or instead of the one or more processors 138 (or, more generally, components) in the controller 102 and the one or more processors 168 (or, more generally, components) in the memory die 104, the data storage device 100 can comprise another set of one or more processors (or, more generally, components). In general, wherever they are located and however many there are, one or more processors (or, more generally, components) in the data storage device 100 can be, individually or in combination, configured to perform various functions, including, but not limited to, the functions described herein and illustrated in the flow charts. For example, the one or more processors (or components) can be in the controller 102, memory device 104, and/or other location in the data storage device 100. Also, different functions can be performed using different processors (or components) or combinations of processors (or components). Further, means for performing a function can be implemented with a controller comprising one or more components (e.g., processors or the other components described above).

Returning again to FIG. 2A, the flash control layer 132 (which will be referred to herein as the flash translation layer (FTL) handles flash errors and interfaces with the host. In particular, the FTL, which may be an algorithm in firmware, is responsible for the internals of memory management and translates writes from the host into writes to the memory 104. The FTL may be needed because the memory 104 may have limited endurance, may be written in only multiples of pages, and/or may not be written unless it is erased as a block. The FTL understands these potential limitations of the memory 104, which may not be visible to the host. Accordingly, the FTL attempts to translate the writes from host into writes into the memory 104.

The FTL may include a logical-to-physical address (L2P) map (sometimes referred to herein as a table or data structure) and allotted cache memory. In this way, the FTL translates logical block addresses (“LBAs”) from the host to physical addresses in the memory 104. The FTL can include other features, such as, but not limited to, power-off recovery (so that the data structures of the FTL can be recovered in the event of a sudden power loss) and wear leveling (so that the wear across memory blocks is even to prevent certain blocks from excessive wear, which would result in a greater chance of failure).

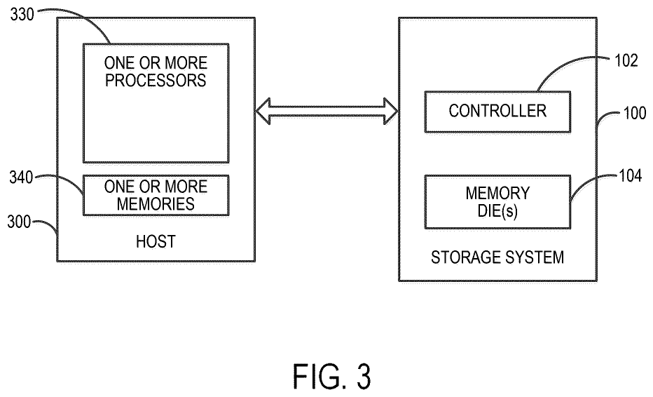

Turning again to the drawings, FIG. 3 is a block diagram of a host 300 and data storage device 100 of an embodiment. The host 300 can take any suitable form, including, but not limited to, a computer, a mobile phone, a tablet, a wearable device, a digital video recorder, a surveillance system, etc. The host 300 in this embodiment (here, a computing device) comprises one or more processors 330 and one or more memories 340. In one embodiment, computer-readable program code stored in the one or more memories 340 configures the one or more processors 330 to perform the acts described herein as being performed by the host 300. So, actions performed by the host 300 are sometimes referred to herein as being performed by an application (computer-readable program code) run on the host 300. For example, the host 300 can be configured to send data (e.g., initially stored in the host's memory 340) to the data storage device 100 for storage in the data storage device's memory 104.

One of the main challenges introduced by NAND process shrinking and 3D stacking is maintaining process uniformity. In addition, products need to support a wide range of operational conditions (such as different program/erase (P/E) cycles, retention times, and temperatures), which can lead to increased variability between memory dies, blocks, and pages across the different operational conditions. Due to these variations, the read thresholds (RT) used for reading a memory page are not fixed and can change significantly as a function of the physical location and the operational conditions, especially for less-mature, new memory nodes.

Reading with inaccurate read thresholds can lead to higher bit error rates (BER), which can degrade performance and quality of service (QoS) due to decoding failures that require invoking high-latency recovery flows, which can cause delays and hiccups in performance.

The challenge of maintaining optimal read thresholds is especially important for enterprise memory systems (for which the quality-of-service requirements can be very strict) and for mobile, Internet of Things (IoT), and automotive memory systems (for which the required range of operational conditions is wide and the frequency of condition changes (e.g., temperature changes) may be relatively high). The problem is even harder during transitions to new, less-mature memory nodes.

Current solutions for read thresholds calibration, such as BER estimation scan (BES) and valley search (VS) can be relatively-high-latency operations aimed at optimizing read thresholds for a specific wordline, which is good for rare read recovery flows in cases of failure to decode the data but may not be suitable for frequent operations in case of frequent read threshold changes. In order to cope with this issue, data storage devices can implement read threshold management schemes that try to track read threshold changes in the background via a maintenance process to ensure that appropriate read thresholds are used when the host issues a read command.

One common approach used in many data storage devices is to track read thresholds per groups of blocks that share the same conditions. More specifically, blocks that are written roughly at the same time and temperature are grouped into time and temperature (TT) groups. Read thresholds are tracked for each TT group, usually acquired on some representative wordline from a block within the group. When the host performs a read operation, the read thresholds associated with the TT group corresponding to the read block are used, wherein additional adaptation to the read thresholds according to the specific read wordline is performed based on pre-calibrated wordline zoning tables.

Unfortunately, existing read threshold management schemes can be suboptimal and not perfectly track the read thresholds under frequently-changing conditions and high variations between memory pages. U.S. patent application Ser. No. 17/838,481, which is hereby incorporated by reference, describes embodiments for performing read threshold calibration by applying a machine learning prediction model. One embodiment presented therein can be used to infer optimal read thresholds from all available information, including TT group information, temperature information, BER information, program-erase count (PEC) information, and physical page location.

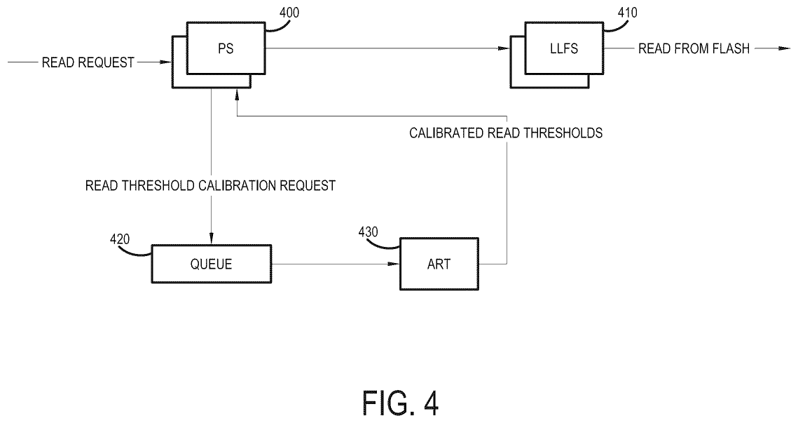

An example architecture is shown in FIG. 4. As shown in FIG. 4, this example architecture comprises a plurality of physical storage (PS) modules 400 (e.g., higher-level processors running the firmware that manages the physical storage), a plurality of low-level flash sequence (LLFS) modules 410 (e.g., lower-level processors running low-level flash sequences), a queue 420, and an artificial intelligence read threshold (“ART”) calibration module 430, which can be implemented in the controller 102 (e.g., using an implementation described in the above-referenced '481 patent application). In this example, the ART module 430 serves several clients, and the PS modules 400 that activate the ART module 420 are each attached to several channels and, eventually, multiple dies. At any given time, there may be several requests for read threshold calibration in the queue 420 for the ART module 430. After the ART module 430 has finished calibrating the read thresholds, it returns the read thresholds directly to the LLFS modules 410, which are responsible for reading from the memory at the calibrated read thresholds.

In one example implementation, the ART module 430 is configured to infer optimized read threshold levels for each and every read. However, for supporting high-throughput reads with a reduced hardware cost (as well as reduced power consumption), it may be desired to bypass the ART module 430 in cases where several read commands with similar conditions are read. The following embodiments address this issue by applying clustering methods on the read requests. More specifically, in contrast to prior read threshold hardware that performs read threshold calculations for every read command, in one embodiment, the controller 102 clusters read requests to provide read threshold calculations quicker and using less power because the hardware calculator does not have to be activated for each read. So, this embodiment can reduce the number of activations of the ART module 430, achieve higher throughput and reduced power consumption, and provide for a reduced ASIC footprint of the ART module 430. In another embodiment, recently-calculated read thresholds are cached, so they can be provided without recalculation if conditions are similar.

In one example implementation, the conditions of the ART module 430 requests are clustered from different clients (e.g., by examining condition(s) of the memory location(s) that are the target of the read requests). Then, the ART module 420 operation can be conducted on cluster representatives, such that the total number of block operations is reduced, without a substantial impact to the results of the read calibration. This can target the selection of representative commands from the queue 420 and, by that, reduce the number of activations of the ART module 430 at a given time. In another embodiment, several read threshold sets are held per several typical condition groups. The controller 102 can correlate each incoming read command to an existing group. In case of a match, the controller 102 can take pre-calculated updated read thresholds (done beforehand by the ART module 430) and skip the actual operation of the ART module 430.

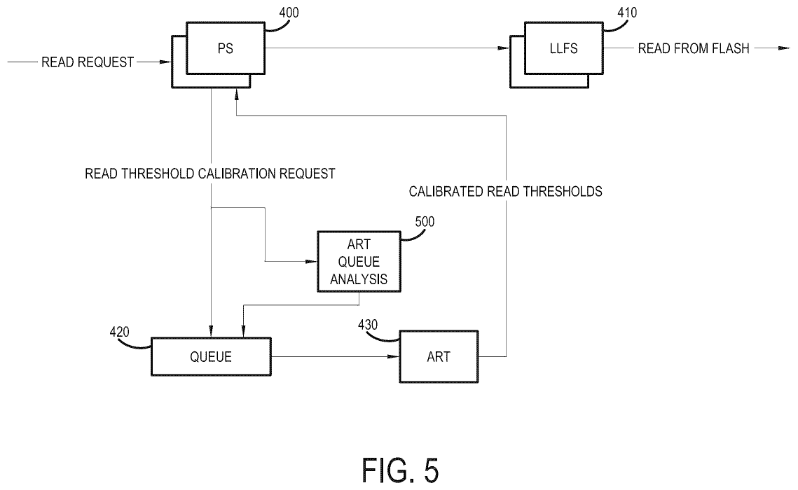

FIG. 5 is an example architecture that can implement these embodiments. As compared to the architecture shown in FIG. 4, this architecture includes an ART queue analysis module 500 that is configured to operate on a current ART queue 420, clustering the requests and providing read threshold calibration results to the LLFS modules 410 without actual operation of the ART module 430.

In one embodiment, an ART queue analysis module 500 is used to receive the read threshold calibration request from the PS modules 400, analyze the request along with the other requests currently in the queue 420, and make decisions regarding the order of operations and potentially reducing the number of ART activations. Within this analysis block, clustering of the different requests may be conducted in order to find a representative for each cluster of requests that would reflect the entire cluster's read thresholds. The representative can be a set of one or more than one.

The calibration can be conducted on all read thresholds of the corresponding logical page. This notion can require that the clustering be done on all the read thresholds. In this way, if even one of them is far from the cluster representative, it would not be considered a good representative. The clustering may be conducted by applying a simple difference function on each of the read thresholds being less than some threshold.

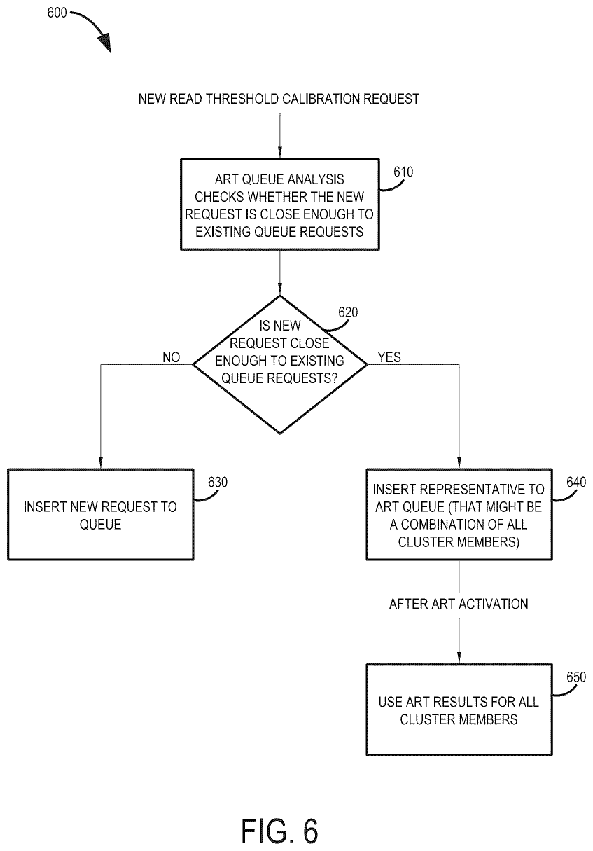

An example implementation is shown in the flow chart 600 in FIG. 6. As shown in FIG. 6, in this example, upon a new read threshold calibration request, the controller 102 of the data storage device 100 performs an analysis of the queue 420 to determine whether the new request is close enough to existing queue requests (610, 620). If the new queue request is not close enough, the new request is inserted into the queue 420 (630). However, if the new queue request is close enough, a representation (which can be a single request or a combination of all cluster members) is inserted into the queue 420 (640). After activation of the ART module 430, the ART results are used for all cluster members to read the memory 104 (650).

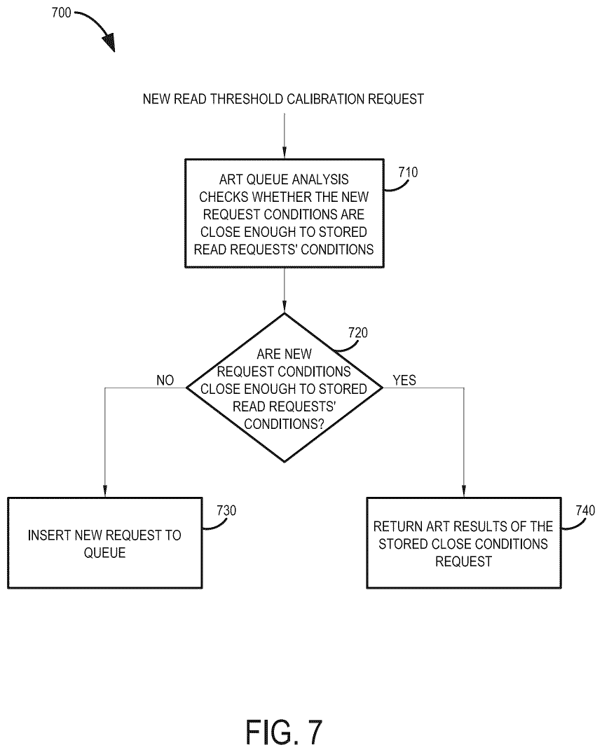

In another embodiment, the last ART activation conditions and the resulting read thresholds can be kept for a short period after of time the activations to provide the results if a request with similar conditions comes shortly after. This may require a small additional memory or it may utilize memory space that is reserved for general use in the controller or even in the host member buffer (HMB). FIG. 7 is a flow chart 700 illustrating this embodiment. As shown in FIG. 7, in this example, upon a new read threshold calibration request, the controller 102 of the data storage device 100 performs an analysis of the queue 420 to determine whether the new request conditions are close enough to stored read request conditions (710, 720). If they are not, the new request is inserted into the queue 420 (730). However, if they are, the controller 102 returns the ART results of the stored close conditions request, which can be used to read the memory 104 (740). In this example, the ART queue analysis block 500 receives the read threshold calibration request from the PS modules 400 and analyzes and compares it to the currently-stored read requests'conditions. If it finds a suitable match, the results of the corresponding read thresholds are returned as the result of the request.

In clustering read-requests conditions groups, the clustering can be targeted to find different read requests that have similar fundamental conditions and, as such, have similar read thresholds. It should be understood that the clustering solution of grouping similar read requests may not replace the fine-tuned solution of the ART module 430. Indeed, there may be cases for which the produced BER difference between implicit ART inference and taking the read thresholds calculated for similar read requests might not justify throughput reduction (in case of a limited ART hardware) and extra power consumption.

The clustering of similar read commands can be based on any suitable memory condition, such as, but not limited to, Timepool and read temperature. Timepool represents a combined measure of accumulated stress applied on the data including time elapsed at different device temperatures. Data with a similar Timepool index and read temperature may have close read thresholds values. Other example conditions include, but are not limited to, block age, a memory die number, a program temperature, a read temperature, a difference between program temperatures of representative wordlines, a cycling level, a data retention level, a wordline number, and/or a measured bit error rate (BER) estimation at a default read temperature.

In another example, in case multiple read commands are targeting the same physical memory entity (e.g., same memory die, memory block, etc.) as in the case of a sequential read operation where the operational conditions between these read commands are fairly stable (e.g., temperature is not shifting), a single ART inferencing operation may serve the multiple read commands (since most of the attributes, such as block age, block time pool, memory die number, temperature, etc.) are identical between the different commands. Additional specific fine tuning can be applied per command according to its specific attributes (e.g., wordline (WL) number or WL zone) on top of the ART read thresholds (inferred based on the shared attributes). The fine tuning per command may be done based on a simple look-up table (LUT) in case the number of specific attributes per command is relatively small (e.g., the specific attribute per command is the WL# or WL zone or Plane or String). The fine tuning using the LUT can be much simpler than applying a full ART inferencing operation per command, thus reducing the power consumption and enabling use of a lower-complexity ART inference engine (e.g., to be operated once per batch of commands instead of per command).

Also, various clustering algorithms can be used, such as, but not limited to, K-means (including many variants such as K-mean++, K-Medians, K-Medoids etc.), GMM, or newer algorithms, such as HDBSCAN. However, the clustering algorithm can be based on simple calculation of a similarity score, which can be calculated between current representative parameter values (such as Timepool and Read Temp) to the representative values of these parameters for each cluster of read commands group.

Finally, as mentioned above, any suitable type of memory can be used. Semiconductor memory devices include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are examples, and memory elements may be otherwise configured.

The semiconductor memory elements located within and/or over a substrate may be arranged in two or three dimensions, such as a two-dimensional memory structure or a three-dimensional memory structure.

In a two-dimensional memory structure, the semiconductor memory elements are arranged in a single plane or a single memory device level. Typically, in a two-dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and wordlines.

A three-dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate).

As a non-limiting example, a three-dimensional memory structure may be vertically arranged as a stack of multiple two-dimensional memory device levels. As another non-limiting example, a three-dimensional memory array may be arranged as multiple vertical columns (e.g., columns extending substantially perpendicular to the major surface of the substrate, i.e., in the y direction) with each column having multiple memory elements in each column. The columns may be arranged in a two-dimensional configuration, e.g., in an x-z plane, resulting in a three-dimensional arrangement of memory elements with elements on multiple vertically stacked memory planes. Other configurations of memory elements in three dimensions can also constitute a three-dimensional memory array.

By way of non-limiting example, in a three-dimensional NAND memory array, the memory elements may be coupled together to form a NAND string within a single horizontal (e.g., x-z) memory device levels. Alternatively, the memory elements may be coupled together to form a vertical NAND string that traverses across multiple horizontal memory device levels. Other three-dimensional configurations can be envisioned wherein some NAND strings contain memory elements in a single memory level while other strings contain memory elements which span through multiple memory levels. Three-dimensional memory arrays may also be designed in a NOR configuration and in a ReRAM configuration.

Typically, in a monolithic three-dimensional memory array, one or more memory device levels are formed above a single substrate. Optionally, the monolithic three-dimensional memory array may also have one or more memory layers at least partially within the single substrate. As a non-limiting example, the substrate may include a semiconductor such as silicon. In a monolithic three-dimensional array, the layers constituting each memory device level of the array are typically formed on the layers of the underlying memory device levels of the array. However, layers of adjacent memory device levels of a monolithic three-dimensional memory array may be shared or have intervening layers between memory device levels.

Then again, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three-dimensional memory arrays. Further, multiple two-dimensional memory arrays or three-dimensional memory arrays (monolithic or non-monolithic) may be formed on separate chips and then packaged together to form a stacked-chip memory device.

Associated circuitry is typically required for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

One of skill in the art will recognize that this invention is not limited to the two dimensional and three-dimensional structures described but cover all relevant memory structures within the spirit and scope of the invention as described herein and as understood by one of skill in the art.

It is intended that the foregoing detailed description be understood as an illustration of selected forms that the invention can take and not as a definition of the invention. It is only the following claims, including all equivalents, that are intended to define the scope of the claimed invention. Finally, it should be noted that any aspect of any of the embodiments described herein can be used alone or in combination with one another.

What is claimed is:

1. A data storage device comprising:
a memory; and
one or more processors, individually or in combination, configured to:
receive a plurality of read requests from a host;
determine a cluster of read requests in the plurality of read requests that are directed to locations in the memory that have similar memory conditions; and
instead of performing a read threshold calibration operation on each read request in the cluster, perform a read threshold calibration operation only on a subset of read requests in the cluster and use a result of the read threshold calibration operation for all read requests in the cluster.

2. The data storage device of claim 1, wherein the one or more processors, individually or in combination, are further configured to determine that the memory conditions are similar by using a difference function to determine that a similarity score associated with the memory conditions is less than a threshold.

3. The data storage device of claim 1, wherein the memory conditions comprise block age, a timepool index, a memory die number, a program temperature, a read temperature, a difference between program temperatures of representative wordlines, a cycling level, a data retention level, a wordline number, and/or a measured bit error rate (BER) estimation at a default read temperature.

4. The data storage device of claim 1, wherein the read threshold calibration operation is performed using an artificial intelligence read threshold (“ART”) calibration hardware module.

5. The data storage device of claim 4, wherein the one or more processors, individually or in combination, are further configured to:
add only the subset of read requests, and not other read requests in the cluster, to a queue for processing by the ART calibration hardware module; and
add read requests from the plurality of read requests that are not in the cluster to the queue for processing by the ART calibration hardware module.

6. The data storage device of claim 4, wherein the ART calibration hardware module is configured to perform a fine-tuning operation on the result of the read threshold calibration operation.

7. The data storage device of claim 6, wherein the fine-tuning operation is performed using a look-up table.

8. The data storage device of claim 1, wherein the subset of read requests comprises a single read request.

9. The data storage device of claim 1, wherein the subset of read requests comprises more than one read request.

10. The data storage device of claim 1, wherein at least some of the read requests in the cluster are from different clients in the host.

11. The data storage device of claim 1, wherein the read requests in the cluster target a same physical entity of the memory.

12. The data storage device of claim 1, wherein the memory comprises a three-dimensional memory.

13. In a data storage device comprising a memory, a method comprising:
caching a plurality of calculated read thresholds;
receiving a read request from a host, wherein the read request is directed to a location in the memory;
determining whether a condition of the location in the memory is similar to a condition associated with one of the cached plurality of calculated read thresholds; and
in response to determining that the condition of the location in the memory is similar to the condition associated with the one of the cached plurality of calculated read thresholds, using the one of the cached plurality of calculated read thresholds for the read request instead of calculating a new read threshold for the read request.

14. The method of claim 13, wherein the plurality of calculated read thresholds are cached in the memory.

15. The method of claim 13, wherein the plurality of calculated read thresholds are cached in a memory in the host.

16. The method of claim 15, wherein the memory in the host comprises a host memory buffer.

17. The method of claim 13, further comprising using a difference function to determine whether a similarity score of the condition of the location in the memory and the condition associated with the one of the cached plurality of calculated read thresholds is less than a threshold.

18. The method of claim 13, wherein the condition of the location in the memory and the condition associated with the one of the cached plurality of calculated read thresholds comprise block age, a timepool index, a memory die number, a program temperature, a read temperature, a difference between program temperatures of representative wordlines, a cycling level, a data retention level, a wordline number, and/or a measured bit error rate (BER) estimation at a default read temperature.

19. The method of claim 13, wherein the plurality of calculated read thresholds are calculated using an artificial intelligence read threshold (“ART”) calibration hardware module.

20. A data storage device comprising:
a memory; and
means for:
receiving a plurality of read requests from a host;
identifying a cluster of read requests in the plurality of read requests that are directed to locations in the memory that have similar conditions; and
instead of performing a read threshold calibration operation on each read request in the cluster, performing a read threshold calibration operation only on a subset of read requests in the cluster and use a result of the read threshold calibration operation for all read requests in the cluster.
